(19) United States
(12) Patent Application Publication
(10) Pub. No.: US 2017/0045579 A1
(43) Pub. Date: Feb. 16, 2017

(54) CPU BIST TESTING OF INTEGRATED CIRCUITS USING SERIAL WIRE DEBUG

(71) Applicant: Texas Instruments Incorporated, Dallas, TX (US)

(72) Inventor: Nelson Kei Leung, Plano, TX (US)

(21) Appl. No.: 14/826,596

(22) Filed: Aug. 14, 2015

(51) Int. Cl. G01R 31/3177; G01R 31/28

(52) U.S. Cl. CPC G01R 31/3177; G01R 31/2851

(57) ABSTRACT

A method of simultaneously built in self-testing (BIST) a sub circuit in a plurality of integrated circuit (IC) chips by embedded microprocessor (CPU) and SRAM memory using 2 to 4 digital pins per IC chip on automatic test equipment (ATE) using a serial wire debug testing protocol. A method of simultaneously built in self-testing (BIST) an embedded nonvolatile memory in a plurality of integrated circuit (IC) chips by embedded microprocessor (CPU) and SRAM memory using 2 to 4 digital pins per IC chip on automatic test equipment (ATE) using a serial wire debug testing protocol.

### FIELD

This invention relates to the field of integrated circuit testing. More particularly, this invention relates to the testing of sub circuits in integrated circuits with embedded SRAM and CPU.

### BACKGROUND

The test cost for complex integrated circuits (IC) such as microcontroller circuits is high because of limitations of the test efficiency and resource utilization between the automatic test equipment (ATE) and the (IC) chip under test (DUT). Microcontroller integrated circuits often include a microprocessor or central processing unit (CPU), embedded memories such as SRAM and other sub circuits such as nonvolatile memory, digital-to-analog converters (DAC), analog-to-digital converters (ADC), and phase-locked-loop circuits (PLL).

The efficiency of the testing of integrated circuit chips with embedded sub circuits and embedded memory is improved significantly by loading test programs and test vectors into embedded SRAM on these integrated circuit chips and then using the microprocessor (MPU) or central processing unit (CPU) resident on the integrated circuit chip to perform self-testing of the embedded nonvolatile memory and other sub circuits. Using a chips CPU to self-test sub circuits is known as built in self-testing BIST or CPU BIST.

A commonly used protocol for CPU BIST is direct memory load, execute, dump (DMLED) in which a test program and test vectors are loaded into embedded SRAM on the integrated circuit chip using approximately 8 digital pins. Typically there is a chip reset pin, one or two control pins, one or two clock pins, and 4 or more general purpose input/output (GPIO) pins through which data is transmitted between the automatic test equipment (ATE) and the integrated circuit chip. In addition to the 8 digital ATE pins, analog ATE pins may be needed during testing. For example, analog ATE pins may be required during testing an embedded memory to supply a voltage level during the measurement of a maximum or minimum voltage at which the embedded memory may be programmed.

Using a DMLED protocol with 8 digital pins, the test program and test vectors can be loaded at a rate of about 4 to 5 MHz. Program loading may require about 1 to 100 msec depending upon the size of the actual test program. The on chip CPU then performs testing of the embedded nonvolatile memory and other sub circuits and writes a pass or fail code into a memory location in the embedded SRAM when testing is complete. The test results are then dumped to the ATE through the 4 general purpose input/output (GPIO) pins. Depending upon the size of the embedded nonvolatile memory and complexity of the other sub circuits, it may take a 100 sec or more to complete the BIST.

Using the DMLED testing protocol with 8 digital pins enables an ATE tester with 256 digital pins to test 32 integrated circuit chips in parallel. Testing chips in parallel reduces the average testing time per chip from 100 sec. per chip to 3.125 sec. Assuming all other analog ATE pins are available as needed for testing, an ATE tester with 512 pins can test 64 integrated circuit chips in parallel cutting the testing time per chip in half The cost of an ATE configured with 512 pins is significantly more than the cost of an ATE with 64 pins so testing cost per chip is a compromise between cost of the tester and the number of chips that can be simultaneously tested in parallel.

### SUMMARY

A method of simultaneously built in self-testing (BIST) a sub circuit in a plurality of integrated circuit (IC) chips by embedded microprocessor (CPU) and SRAM memory using 2 to 4 digital pins per IC chip on automatic test equipment (ATE) using a serial wire debug testing protocol. A method of simultaneously built in self-testing (BIST) an embedded nonvolatile memory in a plurality of integrated circuit (IC) chips by embedded microprocessor (CPU) and SRAM memory using 2 to 4 digital pins per IC chip on automatic test equipment (ATE) using a serial wire debug testing protocol.

### DESCRIPTION OF THE VIEWS OF THE DRAWINGS

FIG. 1 is a plan view of automatic test equipment (ATE) connected to two integrated circuits with an embedded microprocessor or CPU, embedded SRAM, plus other sub circuits with 2 digital pins.

FIG. 2 is a flow diagram of a serial wire debug testing protocol according to embodiments.

FIG. 3 is a flow diagram of a test number execute flow by CPU BIST according to embodiments.

FIG. 4 is a plan view of automatic test equipment (ATE) connected to two integrated circuits with an embedded microprocessor or CPU, embedded SRAM, plus other sub circuits with 3 digital pins.

FIG. 5 is a plan view of automatic test equipment (ATE) connected to two integrated circuits with an embedded microprocessor or CPU, embedded SRAM, plus other sub circuits with 4 digital pins.

### DETAILED DESCRIPTION OF EXAMPLE EMBODIMENTS

Embodiments of the invention are described with reference to the attached figures. The figures are not drawn to scale and they are provided merely to illustrate the invention. Several aspects of the embodiments are described below with reference to example applications for illustration. It should be understood that numerous specific details, relationships, and methods are set forth to provide an understanding of the invention. One skilled in the relevant art, however, will readily recognize that the invention can be practiced without one or more of the specific details or with other methods. In other instances, well-known structures or operations are not shown in detail to avoid obscuring the invention. The present embodiments are not limited by the illustrated ordering of acts or events, as some acts may occur in different orders and/or concurrently with other acts or events. Furthermore, not all illustrated acts or events are required to implement a methodology in accordance with the present invention.

Serial Wire Debug (SWD) is a two-wire protocol alternative to the JTAG (Joint Action Test Protocol) standard used by DMLED. The SWD physical layer which consists of a bi-directional data line (SWDIO) and a clock pin (SWDCLK). SWD interface allows access to debug and access ports of an integrated circuit chip having an embedded microprocessor or CPU, SRAM, and other subsystems or control registers.

The circuit in an IC chip that contains an embedded microprocessor (MPU) or central processing unit (CPU) plus embedded memory may include design for test (DFT) to accommodate built in self-testing (BIST). BIST is significantly faster than external testing of the IC by the ATE. The IC chip may include DFT using a DMLED testing protocol which uses a minimum of 5 digital pins, may include DFT using a SWD testing protocol which uses 2, 3, or 4 digital pins, or may include DFT to accommodate both DMLED and SWD testing protocols. Typically a DMLED testing program utilizes 8 or more digital pins to test each IC chip. In addition to the digital pins, an analog pin or pins may be required to provide a required signal level such as a voltage level during testing.

As described below a 2 pin testing program may be designed to utilize the two SWD pins (SWDCLK and SWDIO) to test the IC chip provided the IC chip has the reset function available with DFT.

Also described below a 3 pin testing program may be designed to utilize the chip reset pin in addition to the two SWD pins.

Also described below a 4 pin testing program may be designed to utilize the chip reset pin and a GPIO pin in addition to the two SWD pins. The GPIO pin may be used to inform the ATE when testing of the IC chip is complete.

Instead of using 8 pins for testing an IC as is typical when using a DMLED testing protocol, 2, 3, or 4 pins may be used with a SWD based testing protocol. Reducing the number of ATE test pins required to test an IC chip enables the ATE to simultaneously test more ICs in parallel.

IC chips may be tested in packages or may be tested in wafer form. When testing the IC chips in packaged form, the pins of the IC chips are inserted into sockets which are connected to the ATE tester pins. When testing the IC chips in wafer form, the ATE tester pins contact probe pads on the IC chips. In the description below, the terms ATE tester pins and IC chip pins will be used, but it is understood that IC chip probe pads may also be used.

Although loading the testing program and testing vectors into the embedded SRAM memory takes slightly longer utilizing the SWD communication interface, the number of integrated circuit chips that may be tested in parallel can be doubled or more than doubled. For example, when loading a test program of 32 KB in size through a DMLED interface at 4 MHz, each write of 4-bit data in parallel takes one cycle of 250 nsec. This results in a program load time to embedded SRAM, including overhead, of about 16 to 20 msec. On the other hand, using the SWD interface at 1 MHz, each write of 1-bit data in serial takes one cycle of 1 msec. This results in a program load time to embedded SRAM of about 250 to 500 msec. Usually the built in self-test (BIST) time is relatively long, so the test program load time represents only a small fraction of the overall test time. This slight increase in test program load time is typically insignificant when compared to the reduction in average test time per chip that is achieved by doubling the number of integrated circuit chips that may now be tested in parallel.

An ATE configured with 512 digital pins can test 64 chips in parallel using an 8 pin test program with the DMLED testing protocol assuming all other analog ATE pins are available as required. Alternatively, the ATE can test 128 chips in parallel using a 4 pin test program with the SWD testing protocol (Again assuming all other analog ATE pins are available as required.) If it takes 100 sec for DMLED testing it may take 101 sec for SWD testing because of the extra time needed to load the test programs serially. That works out to a testing time of about 1.56 sec per chip for DMLED versus a testing time of about 0.79 sec per chip for SWD. In this scenario to achieve the same test throughput as a 4 pin SWD test program requires either two ATE testers with 512 digital pins or requires a more expensive ATE tester with 1,024 digital pins as needed for DMLED testing.

With additional design for test (DFT) features designed into the IC, utilizing the SWD interface, the IC may be tested with 3 digital pins or 2 digital pins. Using DFT features may reduce the number of ATE pins needed to test an IC chip therefore enabling even more chips to be simultaneously tested in parallel additionally reducing testing cost. For example an ATE with 512 digital pins can test 64 chips using the 8 pin DMLED interface, may test 170 chips using a 3 pin test utilizing the SWD interface, or may test 256 chips using a 2 pin test utilizing the SWD interface.

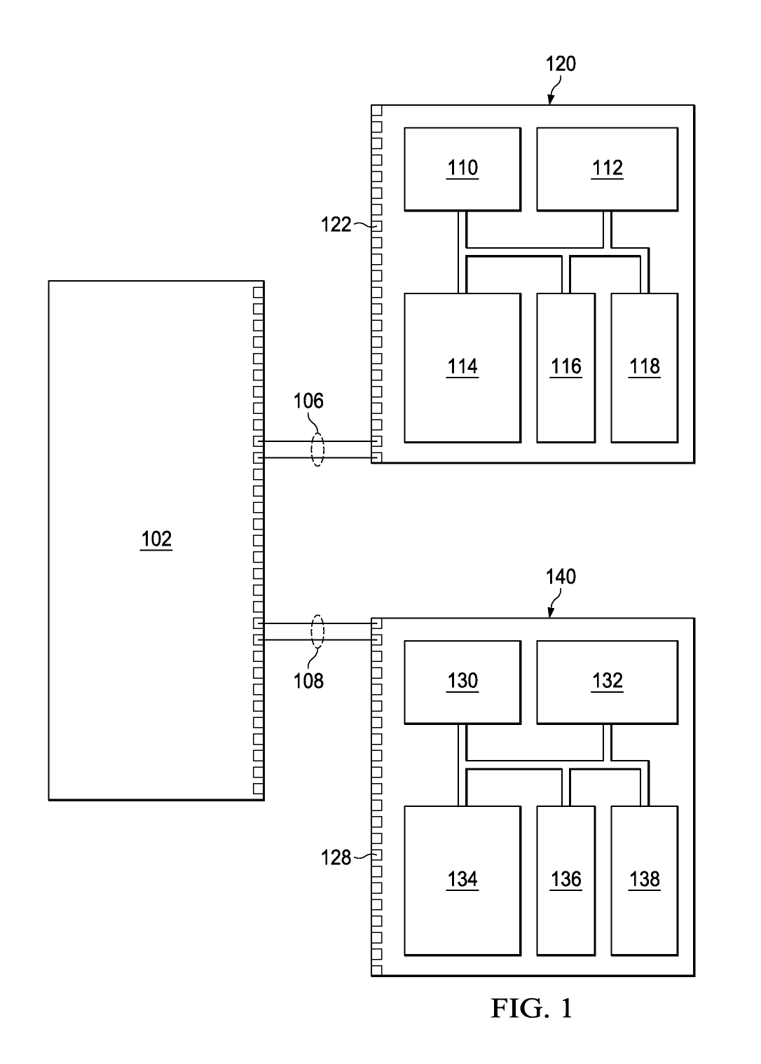

FIG. 1 illustrates an ATE tester 102 capable of testing multiple integrated circuit chips (IC) with embedded SRAM memory and other sub circuits using a 2 pin SWD based testing protocol. The IC chips 120 and 140 must have a design for test (DFT) reset function built into the IC that may be actuated by the BIST program.

As is illustrated in FIG. 1, two digital pins 106 and 108 and two IC probe pads IC pins 122 and 128 may be utilized when testing using a two pin SWD based testing protocol. One pin may be a serial wire clock pin (SWDCLK) and the other pin may be a serial wire data pin (SWDIO).

Two integrated circuit chips, 120 and 140, with a CPU, 110 and 130, embedded SRAM, 112 and 132, and other embedded sub circuits, 114, 116, 118, 134, 136, and 138, are shown in FIG. 1 for illustration. Typically 8, 16, 32, 64, 96, or 128 IC chips are tested in parallel depending upon the number of data pins available on the ATE 102. Test programs and test vectors are loaded from the ATE 102 into the embedded SRAM memory 112 on IC chip 120 through the two ATE digital pins 106. Likewise, test programs and test vectors are simultaneously loaded from the ATE 102 into the embedded SRAM memory 132 on IC chip 140 through two ATE digital pins 108.

CPU 110 on IC chip 120 uses the test programs and test vectors loaded into the embedded SRAM 112 to perform the built in self-test (BIST) of one or more of the sub circuits 114, 116, and 118. For example sub circuit 114 may be embedded nonvolatile memory and sub circuits 116 and 118 may be a DAC, an ADC, a PLL, or other sub circuit. After the testing is completed, the result of the test (a pass code, a fail code, or an error code) and other optional measurement data may be written into a memory location in the embedded SRAM 112. When the ATE 102 determines the testing is complete, by periodically polling the result of a test (a pass code, a fail code, or an error code) from the embedded SRAM 112 memory location, it may run another set of selected tests, or may then exit the test and then test another set of IC chips.

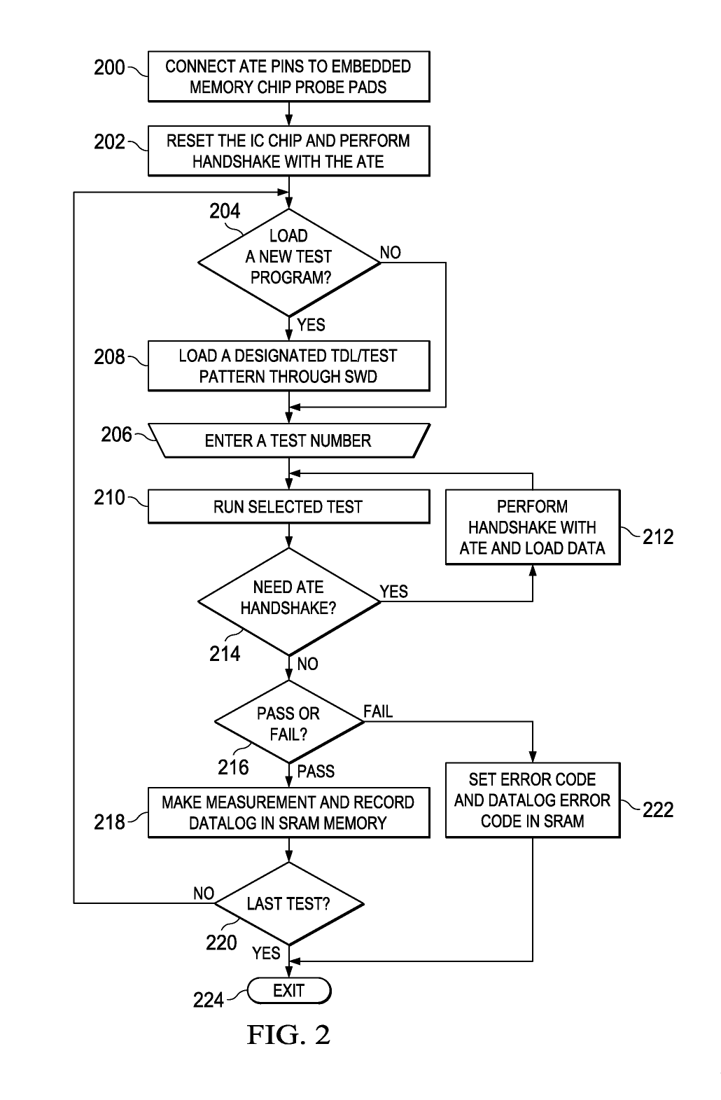

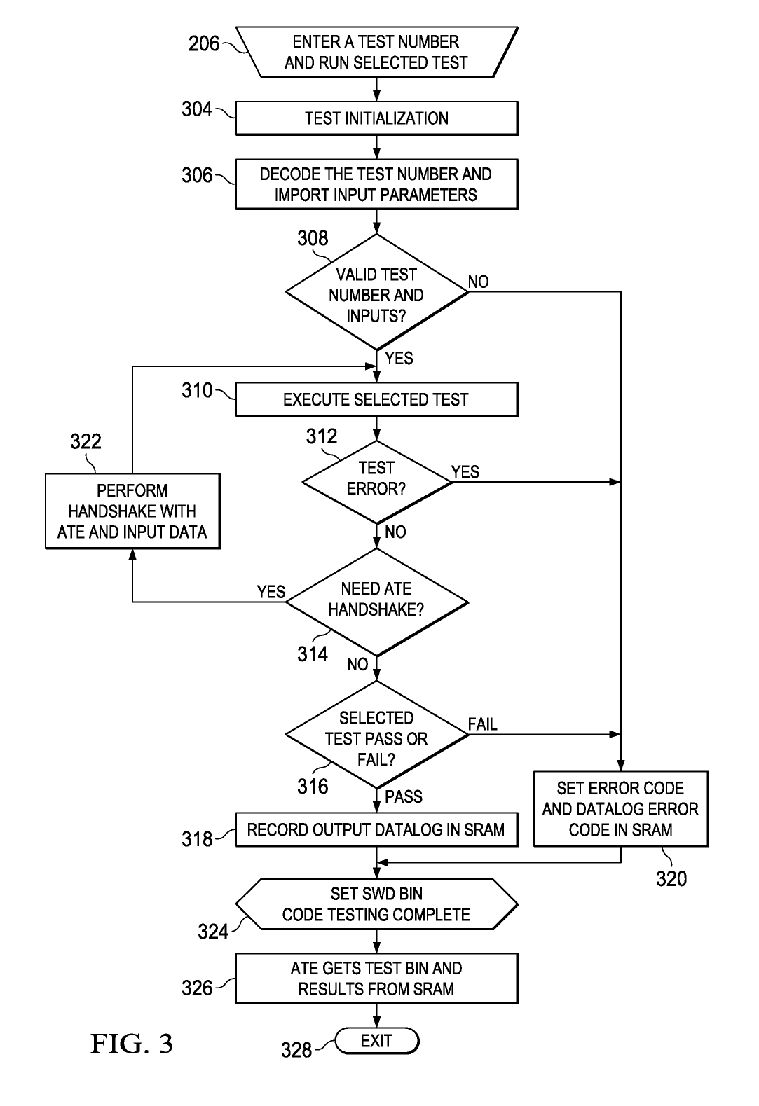

Details of CPU BIST testing by the SWD testing protocol are shown in the testing flow diagrams in FIGS. 2 and 3.

In step 200 in FIG. 2 the ATE tester 102 connects ATE tester pins 106 to the IC pins (if packaged testing) or probe pads (if wafer testing) 122 of IC chip 120 (FIG. 1).

In step 202 the ATE 102 uses the DFT reset function that is built into the IC circuit to initialize the IC chip 120. The CPU 110 then performs a handshake with the ATE 102 to inform the ATE 102 that it is ready for the ATE 102 to begin loading the test program and test vectors into the embedded SRAM memory 112.

In step 204 the decision is made whether to load a new test program from the ATE 102 or to continue with an additional test using a test program already resident in the embedded SRAM memory 112.

If another test is to be run using the existing program the test proceeds to step 206.

If, however, a new test program is to be loaded from the ATE 102 the test proceeds to step 208 and loads the new test program into the embedded SRAM memory 112 through the SWD. Loading of a new test program in step 208 triggers the ATE 102 to also load test vectors from a test description language (TDL) file into the embedded SRAM 112. After the new test program and test vectors are loaded into the embedded SRAM memory 112, the test program proceeds to step 206.

In step 206, a user-defined test number is entered into an SRAM location 112 to instruct the CPU 110 to perform the test corresponding to the test number upon one of the embedded sub circuits 114, 116, 118. For purposes of illustration the testing of an embedded nonvolatile memory 114 is used. For example, one test number may correspond to search for the minimum or maximum programming voltage to the control gate of the non-volatile memory transistor such that the resulting memory pattern matches a predetermined pattern. Another test number may correspond to testing the programming of a checkerboard pattern or an inverse checkerboard pattern into the nonvolatile memory 114. Another test number may correspond to testing the standby current of the embedded nonvolatile memory 114 with all bits programmed or with all bits un-programmed. Other test numbers may correspond to other embedded nonvolatile memory 114 tests. After the test number is entered in step 206 the test program proceeds to step 210.

In step 210 the test specified by the test number input in step 206 is performed. After the test starts execution, it is determined in step 214 if a handshake with the ATE 102 is needed to input additional information to run the test. For example, a particular test number may require special input/output parameters or control sequence to be input from the ATE 102 during testing. The bidirectional handshake between the CPU 110 and ATE 102 may consist of writing or reading the content of an SRAM 112 location having some specific code value. For example, a value in a SRAM 112 location containing 0hAEBB and 0hAEEE (in hexadecimal format) could indicate the request and acknowledge signal of the handshake from the ATE 102 to the CPU. Similarly, the CPU may use a value of 0hCBBB and 0hCBEE (in hexadecimal format) for the request and acknowledge signal to the ATE 102. During the handshake in step 212, either the CPU 110 or the ATE 102 (or both) may properly change the voltage or current level on certain pins or change the programmed pattern in the nonvolatile memory 114 as required by the specified the test number. After the handshake 212 between the CPU 110 and ATE 102 is done, the test may continue and repeat the handshake 212 as needed. The test program proceeds to step 216 upon completion of the test corresponding to the specified test number.

If the handshake is not needed, the test program proceeds directly to step 216 upon completion of the test.

In step 216 the program determines if the test passed or failed. If the test failed the test program proceeds to step 222 where it sets an error code and writes it to a memory location in the embedded SRAM 112 before proceeding to exit the test in step 224. Other optional output measurement data may also be written into other memory locations in embedded SRAM memory 112.

If, on the other hand, the test passes, the test program proceeds to step 218 where the result of the test or a pass code may be written into a memory location in the embedded SRAM 112 memory. Other optional output measurement data may also be written into other memory locations in the SRAM 112. The test program then proceeds to step 220.

In step 220 the test program checks to see if overall testing is complete. If the testing is complete the test program writes a code into a memory location in the SRAM 112 to indicate testing is complete and then proceeds to step 224 to exit the testing.

If, however, the testing is not complete the test program proceeds to step 204 where it is decided if a new test program is to be loaded from the ATE 102 into the embedded SRAM 112 or if another test is to be performed using the current test program.

If another test is to be performed using the current test program, the test program proceeds to step 206 where a new test number is entered to instruct the existing test program which test it is to perform next.

The testing then proceeds as described previously.

Step 206 in FIG. 2 is described in more detail in the test number execute flow diagram illustrated in FIG. 3.

A test number entered into the CPU 110 in step 206 triggers the test program in the CPU 110 in step 304 to initialize the embedded nonvolatile memory (and/or other embedded sub circuits) in preparation for the test specified by the test number.

In step 306 the CPU 110 decodes the test number and imports other input or control parameters as needed and then proceeds to step 308.

In step 308 the CPU 110 checks the validity of the test number and other input or control parameters. If either the test number or a test input or control parameter is invalid, the test program proceeds to step 320, sets an error code and writes the error code into a memory location in the embedded SRAM 112. The CPU 110 then proceeds to set the output bin result in step 324 and writes a code into a memory location in the embedded SRAM 112 indicating the testing is complete. The ATE 102 periodically polls the memory location to see if the code indicating the testing is complete is written there. When the ATE 102 determines the testing is complete, it then reads the test result and possibly other test data from embedded SRAM 112memory locations in step 326. For example, the output bin result may be coded in the SRAM memory 112 as 0hACED (hexadecimal format) to indicate the test has passed whereas 0xhDEAD (hexadecimal format) may be coded to show a test fail or 0hDDDD (hexadecimal format) may indicate a decode error in the test number, or 0hEEEE (hexadecimal format) may indicate an input or control parameter error. The test program then exits in step 328.

If, however, the test number and test patterns are found to be valid in step 308 the test program proceeds to step 310 where the CPU 110 executes the test that corresponds to the test number entered in step 206.

In step 312, after the test is complete the CPU 110 checks to see if an error occurred during test or if the test can continue. If an error occurred during testing, such as a failure in programming the embedded nonvolatile memory 114, the CPU 110 proceeds to step 320 where it sets an error code that describes the type of error that occurred and writes the error code into a memory location in the embedded SRAM memory 112. For example, the SRAM 112 memory location may contain a value of 0hECEC (hexadecimal format) for indicating a programming error of the nonvolatile memory 114, or the SRAM 112 memory location may contain a value of 0hAEAE (hexadecimal format) for showing the actual pass or fail result should be determined by the ATE 102 upon the measurement data meeting the required specification limits. Other values may indicate other kinds of errors.

If, however, no error occurred during testing in step 310, the test program proceeds to step 314 and checks to determine if a handshake is needed between the CPU 110 and ATE 102. If the handshake is needed, the test program proceeds to step 322 to perform any required handshake with ATE 102. The test program then proceeds to step 310 to continue testing.

If in step 314 a handshake is not required the test program proceeds to step 316 to determine whether the BIST testing is complete with a pass or a fail result. If the test passes in step 316, the testing program proceeds to 318 where it writes the passing result (such as output measurement or data) into a memory location in the embedded SRAM 112. The test program then proceeds to step 324 where it may set the SWD bin to indicate the testing is complete. If the test fails in step 316, the test program proceeds to step 320 to write the error code and other optional measurement data into a memory location in the embedded SRAM 112.

In step 326 the ATE 102 polls a memory location in the embedded SRAM 112 to see if the test complete code is present. When The ATE 102 determines the test is complete it reads the test bin and testing results from SRAM 112 memory locations through the SWD interface.

The CPU 110 then proceeds to step 328 to exit the specified test.

If it is determined in step 316 that the test failed the test program proceeds to step 320 and exits the program as described previously.

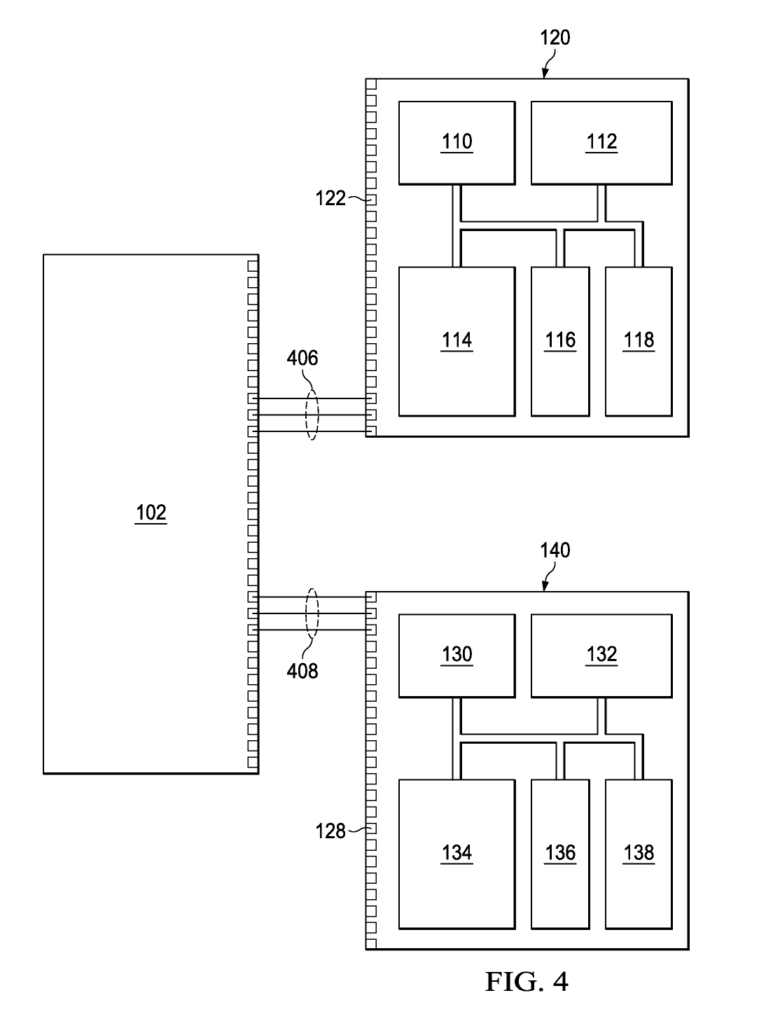

Some IC chips may have the SWD interface but may not have the built in DFT feature to reset the sub circuits using a testing program. For these chips the IC chip reset pin or reset probe pad may be used. As shown in FIG. 4, the testing of the IC chips, 120 and 140 may be performed using 3 pins, 406 and 408. The three pins, 406 and 408, may be a SWD clock pin, a SWD data pin, and an IC chip reset pin.

In this test method the ATE 102 periodically reads the SRAM 112 memory location (step 326, FIG. 3) to determine if IC chip 120 has completed the BIST testing. If the test is complete the ATE 102 then reads a pass or fail code in a SRAM 112 memory location. Additionally the ATE 102 may read an error code from another SRAM 112 memory location to determine the type of failure that occurred or other optional output measurement data. Similarly, when the test passes, the ATE 102 may read other optional output measurement data from SRAM 112 memory locations to identify the location of each chip within a specification range.

It takes time for the ATE 102 to periodically read a memory location in the embedded SRAM 112 to determine if the BIST is complete. An option that requires less time is to set a level on a general purpose I/O (GPIO) pin such as from high-to-low or from low-to-high to indicate when BIST is complete. The ATE 102 may poll the GPIO pin periodically to determine if the BIST testing is complete. While this option reduces testing time it also reduces the number of IC chips that may be tested in parallel. For some IC circuits, this trade off favors shorter testing time.

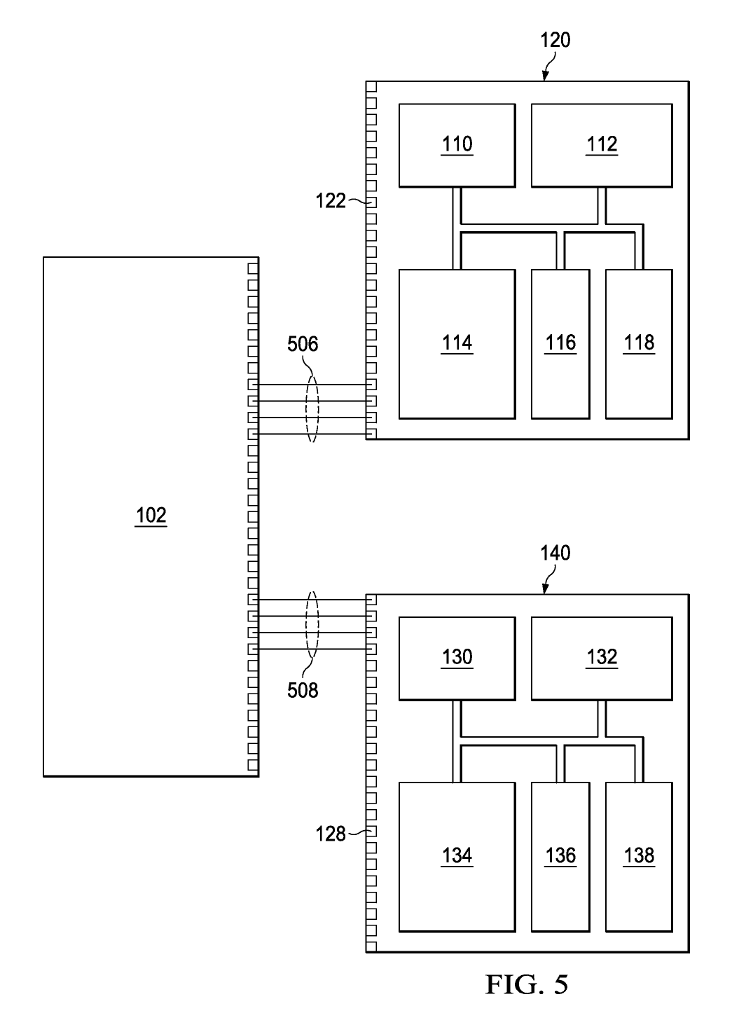

Alternatively, as shown in FIG. 5, the testing of the IC chips, 120 and 140 may be performed using 4 pins, 506 and 508, utilizing the SWD interface. One pin may be a reset pin, one pin may be a serial wire clock pin (SWDCLK), one pin may be a serial wire data pin (SWDIO), and one pin may be a GPIO pin.

With the SWD testing protocol using a 4 pin program as described in FIG. 5, CPU BIST testing uses a test method similar to the SWD testing protocol using a 3 pin program with the addition of setting a level on a GPIO pin when testing is complete. Instead of the ATE 102 periodically reading an embedded SRAM 112 memory location to determine if BIST is complete, the ATE 102 periodically checks the level on the GPIO pin. Checking a level on a GPIO pin takes less time than reading a test completion code from a memory location in the embedded SRAM 112 and therefore reduces testing time.

While various embodiments of the present invention have been described above, it should be understood that they have been presented by way of example only and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. A method of simultaneously testing a plurality of integrated circuit chips in parallel, comprising:
an automatic testing equipment (ATE) tester with a plurality of ATE digital pins;
a testing program in a memory of the ATE wherein the testing program utilizes a serial wire debug (SWD) protocol for communicating with a IC chip;
an embedded microprocessor unit (MPU) or central processing unit (CPU) in each of the plurality of integrated circuit chips;
embedded SRAM in each of the plurality of integrated circuit chips;
a sub circuit in each of the plurality of integrated circuit chips;
assigning 2 to 4 ATE digital pins to each of the plurality of integrated circuit chips wherein a first ATE digital pin is a bidirectional serial wire data pin (SWDIO) pin and a second ATE digital pin is a serial wire clock pin (SWDCLK) pin;
simultaneously contacting 2 to 4 ATE pins to probe pads or to IC pins on each of the plurality of integrated circuit chips;
the testing program simultaneously loading a built in self-testing (BIST) sub circuit test program and test vectors into embedded SRAM memory on each of the plurality of integrated circuit chips using the SWD communication protocol;
the MPU or CPU on each of the plurality of integrated circuit chips performing the BIST of the sub circuit using the BIST embedded sub circuit testing program;
at the end of the BIST the MPU or CPU on each of the plurality of integrated circuit chips writing a pass or fail code into a memory location in the embedded SRAM on each of the plurality of integrated circuit chips;
the ATE periodically checking to see if the BIST is complete;
the ATE reading data from a memory location in the embedded SRAM when the BIST is complete; and
the ATE exiting the testing.

2. The method of claim 1, wherein the sub circuit is a FLASH, EEPROM, or EPROM nonvolatile memory.

3. The method of claim 1, wherein the sub circuit is a ferroelectric nonvolatile memory.

4. The method of claim 1, wherein the sub circuit is an analog-to-digital converter, a digital-to-analog converter, or a phase-locked-loop circuit.

5. The method of claim 1 further comprising:
each of the plurality of integrated circuit chips includes a designed in reset function;
contacting 2 ATE pins to each of the plurality of integrated circuit chips;
utilizing a 2 pin testing protocol;
the 2 pin testing protocol employs the designed in reset function to initialize the sub circuits on the IC chips;
the CPU writing a code into a memory location in the embedded SRAM to indicate when the test is complete; and
the ATE periodically reading the memory location to determine when the test is complete.

6. The method of claim 1 further comprising:
a reset IC pin or a reset probe pad on each of the plurality of integrated circuits;
contacting 3 ATE pins to each of the plurality of integrated circuit chips;
utilizing a 3 pin testing protocol;
the 3 pin testing protocol employing the reset IC pin or reset probe pad to initialize the sub circuits;
the CPU writing a code into a memory location in the embedded SRAM when the test is complete; and
the ATE periodically reading the memory location to determine when the test is complete.

7. The method of claim 1 further comprising:
a reset IC pin or a reset probe pad on each of the plurality of integrated circuits;
a general purpose input/output (GPIO) pin on each of the plurality of integrated circuits;
contacting 4 ATE pins to each of the plurality of integrated circuit chips;
utilizing a 4 pin testing protocol;
the 4 pin testing protocol using the reset IC pin or reset probe pad to initialize the sub circuits;
the CPU changing a signal level on the GPIO pin when the test is complete; and
the ATE periodically reading the level on the GPIO to determine when the test is complete.

8. A method of simultaneously testing a plurality of integrated circuit chips in parallel, comprising:
an automatic testing equipment (ATE) tester with a plurality of ATE digital pins;
an embedded microprocessor unit (MPU) or central processing unit (CPU) in each of the plurality of integrated circuit chips;
embedded SRAM in each of the plurality of integrated circuit chips;
an embedded nonvolatile memory on each of the plurality of integrated circuit chips;
assigning at 2 to 4 ATE digital pins to each of the plurality of integrated circuit chips wherein a first ATE digital pin is a bidirectional serial wire data pin (SWDIO) pin and a second ATE digital pin is a serial wire clock pin (SWDCLK) pin;
simultaneously contacting at 2 to 4 ATE digital pins to probe pads or IC pins on each of the plurality of integrated circuit chips;
the testing program simultaneously loading a built in self-testing (BIST) sub circuit test program and test vectors into embedded SRAM memory on each of the plurality of integrated circuit chips using a SWD interface and SWD communication protocol;
the MPU or CPU on each of the plurality of integrated circuit chips performing the BIST of the embedded nonvolatile memory using the BIST embedded sub circuit testing program;
at the end of the BIST the MPU or CPU on each of the plurality of integrated circuit chips writing a pass or fail code into a memory location in the embedded SRAM on each of the plurality of integrated circuit chips;
the ATE periodically checking to see if the BIST is complete;
the ATE reading data from a memory location in the embedded SRAM when the BIST is complete; and
the ATE exiting the testing.

9. The method of claim 8, wherein the embedded nonvolatile memory is a FLASH, EEPROM, or EPROM nonvolatile memory.

10. The method of claim 8, wherein the embedded nonvolatile memory is a ferroelectric nonvolatile memory.

11. The method of claim 8, further including BIST testing of at least one of an analog-to-digital converter, a digital-to-analog converter, or a phase-locked-loop circuit.

12. The method of claim 8 further comprising:
each of the plurality of integrated circuit chips includes a designed in reset function;
contacting 2 ATE pins to each of the plurality of integrated circuit chips;
utilizing a 2 pin testing protocol;
the 2 pin testing protocol employing the designed in reset function to initialize the embedded nonvolatile memory;
the CPU writing a code into a memory location in the embedded SRAM when the test is complete; and
the ATE periodically reading the memory location to determine when the test is complete.

13. The method of claim 8 further comprising:
a reset IC pin or reset probe pad on each of the plurality of integrated circuits;
contacting 3 ATE pins to each of the plurality of integrated circuit chips;
utilizing a 3 pin testing protocol;
the 3 pin testing protocol employing the reset IC pin or reset probe pad to initialize the nonvolatile memory;
the CPU writing a code into a memory location in the embedded SRAM when the test is complete; and
the ATE periodically reading the memory location to determine when the test is complete.

14. The method of claim 1 further comprising:
a reset pin on each of the plurality of integrated circuits;
a general purpose input/ output (GPIO) pin on each of the plurality of integrated circuits;
contacting 4 ATE pins to each of the plurality of integrated circuit chips;
utilizing a 4 pin testing protocol;
the 4 pin testing protocol employs the reset pin to initialize the nonvolatile memory;
the CPU changing a signal level on the GPIO pin when the test is complete; and
the ATE periodically reading the level on the GPIO pin to determine when the test is complete.
